(19) United States
(12) Patent Application Publication
(10) Pub. No.: US 2026/0121670 A1
(43) Pub. Date: Apr. 30, 2026

(54) IMPEDANCE MATCHING USING A TRAFFIC PATTERN IN A WIRELESS COMMUNICATION SYSTEM

(71) Applicant: QUALCOMM Incorporated, San Diego, CA (US)

(72) Inventors: Derrick Albert Chu, San Diego, CA (US); Harish Venkatachari, San Jose, CA (US); Raghu Narayan Challa, San Diego, CA (US); David Loweth Winslow, San Diego, CA (US); Erwin Spits, Utrecht (NL); Arash Ebadi Shahrivar, San Diego, CA (US); Bharath Keshavamurthy, Sunnyvale, CA (US); Michael Lee McCloud, San Diego, CA (US)

(21) Appl. No.: 18/930,795

(22) Filed: Oct. 29, 2024

(51) Int. Cl. H04B 1/04; H04W 24/02

(52) U.S. Cl. CPC H04B 1/0458; H04W 24/02

(57) ABSTRACT

An apparatus for wireless communication includes a processing system. The processing system includes one or more processors and one or more memories coupled to the one or more processors. The processing system is configured to dynamically adjust antenna impedance matching circuitry in accordance with a codeword and as a function of a traffic pattern. The processing system is further configured to perform a wireless communication operation associated with the traffic pattern and in accordance with the codeword.

### TECHNICAL FIELD

Aspects of the present disclosure relate generally to wireless communication systems, and more particularly, to impedance matching in a wireless communication system.

### DESCRIPTION OF THE RELATED TECHNOLOGY

Wireless communication networks are widely deployed to provide various communication services such as voice, video, packet data, messaging, broadcast, and the like. These wireless networks may be multiple-access networks capable of supporting multiple users by sharing the available network resources. Such networks may be multiple access networks that support communications for multiple users by sharing the available network resources.

A wireless communication network may include several components. These components may include wireless communication devices, such as base stations (or node Bs) that may support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on a downlink to a UE or may receive data and control information on an uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

Wireless communication devices increasingly use antennas to communicate wireless signals. Techniques such as multiple-input, multiple-output (MIMO) and carrier aggregation (CA) may increase the amount of data communicated between wireless communication devices and may also involve a relatively large number of antennas. The antennas may be “tuned” using an antenna tuner (e.g., to adjust for an impedance mismatch and other conditions). A particular setting of an antenna tuner may be referred to as, or may correspond to, an antenna tuner codeword.

Some wireless communication devices increasing use large display screens and large batteries. Such display screens and batteries may reduce or limit the amount of physical space for such antennas and antenna tuners. As a result, performance of some such wireless communication devices may be reduced or limited.

### SUMMARY

The systems, methods and devices of this disclosure each have several innovative aspects, no single one of which is solely responsible for the desirable attributes disclosed herein.

In some aspects, an apparatus for wireless communication includes a processing system including one or more processors and one or more memories coupled to the one or more processors. The processing system is configured to dynamically adjust antenna impedance matching circuitry in accordance with a codeword and as a function of a traffic pattern. The processing system is further configured to perform a wireless communication operation associated with the traffic pattern and in accordance with the codeword.

In some additional aspects, a method of wireless communication performed by a device includes dynamically adjusting antenna impedance matching circuitry in accordance with a codeword and as a function of a traffic pattern. The method further includes performing a wireless communication operation associated with the traffic pattern and in accordance with the codeword.

In some further aspects, a non-transitory computer-readable medium stores instructions executable by one or more processors to initiate, perform, or control operations. The operations include dynamically adjusting antenna impedance matching circuitry in accordance with a codeword and as a function of a traffic pattern. The operations further include performing a wireless communication operation associated with the traffic pattern and in accordance with the codeword.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 is a diagram illustrating an example wireless communication system.

FIG. 2 is a block diagram illustrating examples of a base station and a user equipment (UE).

FIG. 3 is a block diagram illustrating an example wireless communication system that supports traffic pattern based impedance matching.

FIG. 4 is a block diagram illustrating examples of operations that support traffic pattern based impedance matching.

FIG. 5 is a diagram illustrating examples of graphs that may be associated with traffic pattern based impedance matching.

FIG. 6 is a block diagram illustrating additional examples of operations that support traffic pattern based impedance matching.

FIG. 7 is a flow chart of an example of a method of wireless communication that supports traffic pattern based impedance matching.

FIG. 8 is a block diagram of an example UE that supports traffic pattern based impedance matching.

Like reference numbers and designations in the various drawings indicate like elements.

### DETAILED DESCRIPTION

In some aspects of the disclosure, a wireless communication device may perform traffic pattern based impedance matching that includes selecting codewords for impedance matching based at least in part on data traffic associated with the wireless communication device. In some examples, the wireless communication device may use a codebook of codewords and may determine multiple subsets of the codebook that are “best” or “optimal” for different wireless communication operations based on the data traffic, such as based on a pattern associated with the data traffic.

To illustrate, the multiple subsets may include a subset associated with transmit operations and may further include another subset associated with receive operations. Alternatively, or in addition, the multiple subsets may include different subsets associated with different respective component carriers (CCs). Alternatively, or in addition, the multiple subsets may include different subsets associated with different respective wireless communication techniques, such as cellular communications, wireless local area network (WLAN) communications, and wireless personal area network (WPAN) communications.

The wireless communication device may “restrict” among the multiple subsets, which may include determining an intersection of the multiple subsets. The intersection may correspond to a restricted set of codewords that are common to each of the multiple subsets. The wireless communication device may select a particular codeword from among the restricted set of codewords (e.g., by selecting the “best” codeword from among the restricted set of codewords). In some examples, the wireless communication device may select the particular codeword based on evaluating a parameter for each of the restricted sets of codewords, such as a bits-per-joule parameter, or another parameter.

By selecting a codeword based on the traffic pattern associated with a wireless communication operation, performance may be improved as compared to some other techniques, such as a technique that involves optimizing a minimum channel quality metric. For example, by selecting a codeword based on an intersection of multiple subsets of codewords of a codebook, the selected codeword may be optimized for a particular wireless communication operation. As a result, impedance matching may be enhanced for the particular wireless communication operation, which may improve quality and reliability of wireless communications. Further, by enhancing impedance matching, the wireless communication device may avoid increasing the size of the antenna and antenna impedance matching circuitry to compensate for reduced performance. As a result, one or more features herein may support an increase in size of one or more components (such as a display screen or a battery) by reducing the size of an antenna, antenna impedance matching circuitry, or both.

In some implementations, one or more features described herein may be used in connection with wireless communication networks including code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5th Generation (5G) or new radio (NR) networks (sometimes referred to as “5G NR” networks, systems, or devices), 6th Generation (6G) networks, and other communications networks. As described herein, the terms “networks” and “systems” may be used interchangeably.

A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. GERAN is the radio component of GSM/EDGE, together with the network that joins the base stations (for example, the Ater and Abis interfaces) and the base station controllers (A interfaces, etc.). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may comprise one or more GERANs, which may be coupled with UTRANs in the case of a UMTS/GSM network. Additionally, an operator network may also include one or more LTE networks, or one or more other networks. The various different network types may use different radio access technologies (RATs) and RANs.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP2). These various radio technologies and standards are known or are being developed. For example, the 3GPP is a collaboration between groups of telecommunications associations that aims to define a globally applicable third generation (3G) mobile phone specification. 3GPP LTE is a 3GPP project which was aimed at improving UMTS mobile phone standard. The 3GPP may define specifications for the next generation of mobile networks, mobile systems, and mobile devices. The present disclosure may describe certain aspects with reference to LTE, 4G, or 5G NR technologies; however, the description is not intended to be limited to a specific technology or application, and one or more aspects described with reference to one technology may be understood to be applicable to another technology. Additionally, one or more aspects of the present disclosure may be related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ˜1 M nodes/km\hat{ }2), ultra-low complexity (e.g., ˜10 s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 millisecond (ms)), and users with wide ranges of mobility or lack thereof; and (3) with enhanced mobile broadband including extreme high capacity (e.g., ˜10 Tbps/km\hat{ }2), extreme data rates (e.g., multi-Gbps rate, 100+ Mbps user experienced rates), and deep awareness with advanced discovery and optimizations.

Devices, networks, and systems may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz-7.125 GHZ) and FR2 (24.25 GHZ-52.6 GHZ). The frequencies between FR1 and FR2 are often referred to as mid-band frequencies. Although a portion of FR1 is greater than 6 GHZ, FR1 is often referred to (interchangeably) as a “sub-6 GHz” band in various documents and articles. A similar nomenclature issue sometimes occurs with regard to FR2, which is often referred to (interchangeably) as a “millimeter wave” (mmWave) band in documents and articles, despite being different from the extremely high frequency (EHF) band (30 GHZ-300 GHz) which is identified by the International Telecommunications Union (ITU) as a “mmWave” band.

With the above aspects in mind, unless specifically stated otherwise, it should be understood that the term “sub-6 GHz” or the like if used herein may broadly represent frequencies that may be less than 6 GHZ, may be within FR1, or may include mid-band frequencies. Further, unless specifically stated otherwise, it should be understood that the term “mmWave” or the like if used herein may broadly represent frequencies that may include mid-band frequencies, may be within FR2, or may be within the EHF band.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) design or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHZ FDD or TDD implementations, subcarrier spacing may occur with 15 kHz, for example over 1, 5, 10, 20 MHz, and the like bandwidth. For other various outdoor and small cell coverage deployments of TDD greater than 3 GHZ, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mm Wave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

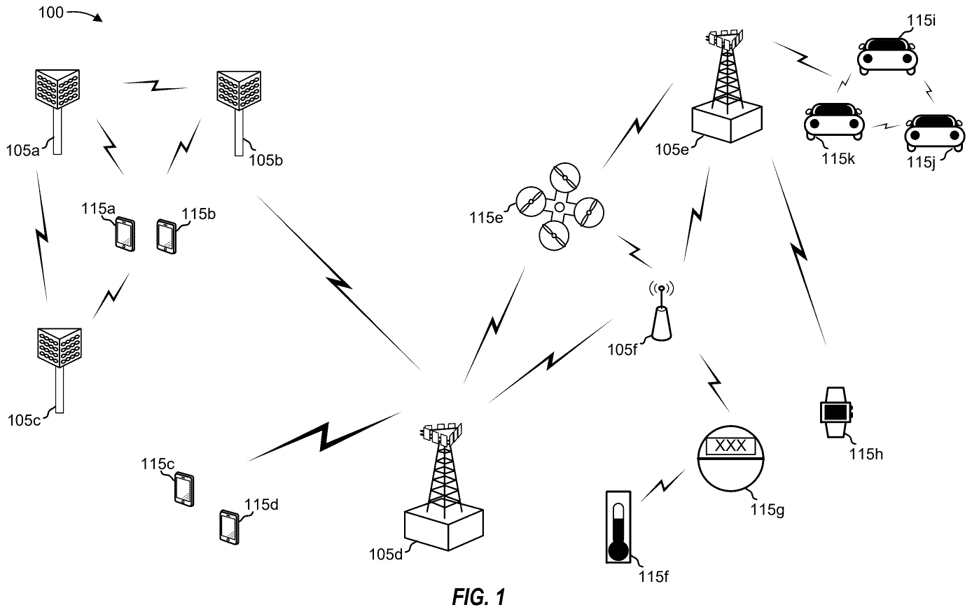

FIG. 1 is a block diagram illustrating details of an example wireless communication system according to one or more aspects. The wireless communication system may include wireless network 100. Wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements (e.g., device to device or peer to peer or ad hoc network arrangements, etc.).

Wireless network 100 illustrated in FIG. 1 includes a number of base stations 105 and other network entities. A base station may be a station that communicates with the UEs and may also be referred to as an evolved node B (eNB), a next generation eNB (gNB), an access point, and the like. Each base station 105 may provide communication coverage for a particular geographic area. In 3GPP, the term “cell” may refer to this particular geographic coverage area of a base station or a base station subsystem serving the coverage area, depending on the context in which the term is used. In implementations of wireless network 100 herein, base stations 105 may be associated with a same operator or different operators (e.g., wireless network 100 may include a plurality of operator wireless networks). Additionally, in implementations of wireless network 100 herein, base station 105 may provide wireless communications using one or more of the same frequencies (e.g., one or more frequency bands in licensed spectrum, unlicensed spectrum, or a combination thereof) as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple (e.g., two, three, four, and the like) cells.

Wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 115 are dispersed throughout the wireless network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc.; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 115a-115d of the implementation illustrated in FIG. 1 are examples of mobile smart phone-type devices accessing wireless network 100 A UE may also be a machine specifically configured for connected communication, including machine type communication (MTC), enhanced MTC (eMTC), narrowband IoT (NB-IoT) and the like. UEs 115e-115k illustrated in FIG. 1 are examples of various machines configured for communication that access wireless network 100.

A mobile apparatus, such as UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 100 may occur using wired or wireless communication links.

In operation at wireless network 100, base stations 105a-105c serve UEs 115a and 115b using 3D beamforming and coordinated spatial techniques, such as coordinated multipoint (CoMP) or multi-connectivity. Macro base station 105d performs backhaul communications with base stations 105a-105c, as well as small cell, base station 105f. Macro base station 105d also transmits multicast services which are subscribed to and received by UEs 115c and 115d. Such multicast services may include mobile television or stream video, or may include other services for providing community information, such as weather emergencies or alerts, such as Amber alerts or gray alerts.

Wireless network 100 of implementations supports mission critical communications with ultra-reliable and redundant links for mission critical devices, such as UE 115e, which is a drone. Redundant communication links with UE 115e include from macro base stations 105d and 105e, as well as small cell base station 105f. Other machine type devices, such as UE 115f (thermometer), UE 115g (smart meter), and UE 115h (wearable device) may communicate through wireless network 100 either directly with base stations, such as small cell base station 105f, and macro base station 105e, or in multi-hop configurations by communicating with another user device which relays its information to the network, such as UE 115f communicating temperature measurement information to the smart meter, UE 115g, which is then reported to the network through small cell base station 105f. Wireless network 100 may also provide additional network efficiency through dynamic, low-latency TDD communications or low-latency FDD communications, such as in a vehicle-to-vehicle (V2V) mesh network between UEs 115i-115k communicating with macro base station 105e.

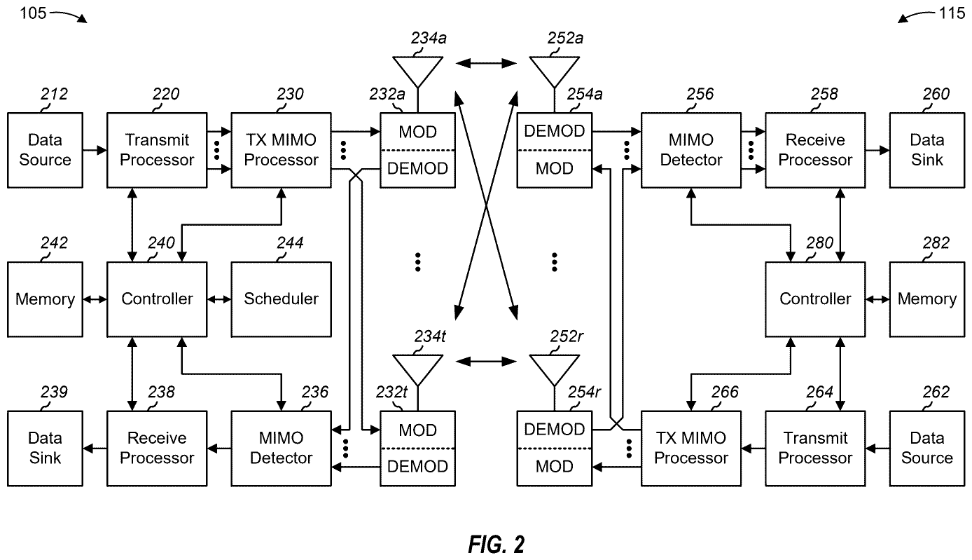

FIG. 2 is a block diagram illustrating examples of base station 105 and UE 115 according to one or more aspects. Base station 105 and UE 115 may be any of the base stations and one of the UEs in FIG. 1. For a restricted association scenario (as mentioned above), base station 105 may be small cell base station 105f in FIG. 1, and UE 115 may be UE 115c or 115d operating in a service area of base station 105f, which in order to access small cell base station 105f, would be included in a list of accessible UEs for small cell base station 105f. Base station 105 may also be a base station of some other type. As shown in FIG. 2, base station 105 may be equipped with antennas 234a through 234t, and UE 115 may be equipped with antennas 252a through 252r for facilitating wireless communications.

At base station 105, transmit processor 220 may receive data from data source 212 and control information from controller 240, such as a processor. The control information may be for a physical broadcast channel (PBCH), a physical control format indicator channel (PCFICH), a physical hybrid-ARQ (automatic repeat request) indicator channel (PHICH), a physical downlink control channel (PDCCH), an enhanced physical downlink control channel (EPDCCH), an MTC physical downlink control channel (MPDCCH), etc. The data may be for a physical downlink shared channel (PDSCH), etc. Additionally, transmit processor 220 may process (e.g., encode and symbol map) the data and control information to obtain data symbols and control symbols, respectively. Transmit processor 220 may also generate reference symbols, e.g., for the primary synchronization signal (PSS) and secondary synchronization signal (SSS), and cell-specific reference signal. Transmit (TX) MIMO processor 230 may perform spatial processing (e.g., precoding) on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream (e.g., for OFDM, etc.) to obtain an output sample stream. Each modulator 232 may additionally or alternatively process (e.g., convert to analog, amplify, filter, and upconvert) the output sample stream to obtain a downlink signal. Downlink signals from modulators 232a through 232t may be transmitted via antennas 234a through 234t, respectively.

At UE 115, antennas 252a through 252r may receive the downlink signals from base station 105 and may provide received signals to demodulators (Demolds) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. MIMO detector 256 may obtain received symbols from demodulators 254a through 254r, perform MIMO detection on the received symbols if applicable, and provide detected symbols. Receive processor 258 may process (e.g., demodulate, deinterleave, and decode) the detected symbols, provide decoded data for UE 115 to data sink 260, and provide decoded control information to controller 280, such as a processor.

On the uplink, at UE 115, transmit processor 264 may receive and process data (e.g., for a physical uplink shared channel (PUSCH)) from data source 262 and control information (e.g., for a physical uplink control channel (PUCCH)) from controller 280. Additionally, transmit processor 264 may also generate reference symbols for a reference signal. The symbols from transmit processor 264 may be precoded by TX MIMO processor 266 if applicable, further processed by modulators 254a through 254r (e.g., for SC-FDM, etc.), and transmitted to base station 105. At base station 105, the uplink signals from UE 115 may be received by antennas 234, processed by demodulators 232, detected by MIMO detector 236 if applicable, and further processed by receive processor 238 to obtain decoded data and control information sent by UE 115. Receive processor 238 may provide the decoded data to data sink 239 and the decoded control information to controller 240.

Controllers 240 and 280 may direct the operation at base station 105 and UE 115, respectively. Controller 240 or other processors and modules at base station 105 or controller 280 or other processors and modules at UE 115 may perform or direct the execution of one or more operations described herein. Memories 242 and 282 may store data and program codes for base station 105 and UE 115, respectively. Scheduler 244 may schedule UEs for data transmission on the downlink or the uplink.

In some cases, UE 115 and base station 105 may operate in a shared radio frequency spectrum band, which may include licensed or unlicensed (e.g., contention-based) frequency spectrum. In an unlicensed frequency portion of the shared radio frequency spectrum band, UEs 115 or base stations 105 may traditionally perform a medium-sensing procedure to contend for access to the frequency spectrum. For example, UE 115 or base station 105 may perform a listen-before-talk or listen-before-transmitting (LBT) procedure such as a clear channel assessment (CCA) prior to communicating in order to determine whether the shared channel is available. In some implementations, a CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. A CCA also may include detection of specific sequences that indicate use of the channel. For example, another device may transmit a specific preamble prior to transmitting a data sequence. In some cases, an LBT procedure may include a wireless node adjusting its own backoff window based on the amount of energy detected on a channel or the acknowledge/negative-acknowledge (ACK/NACK) feedback for its own transmitted packets as a proxy for collisions.

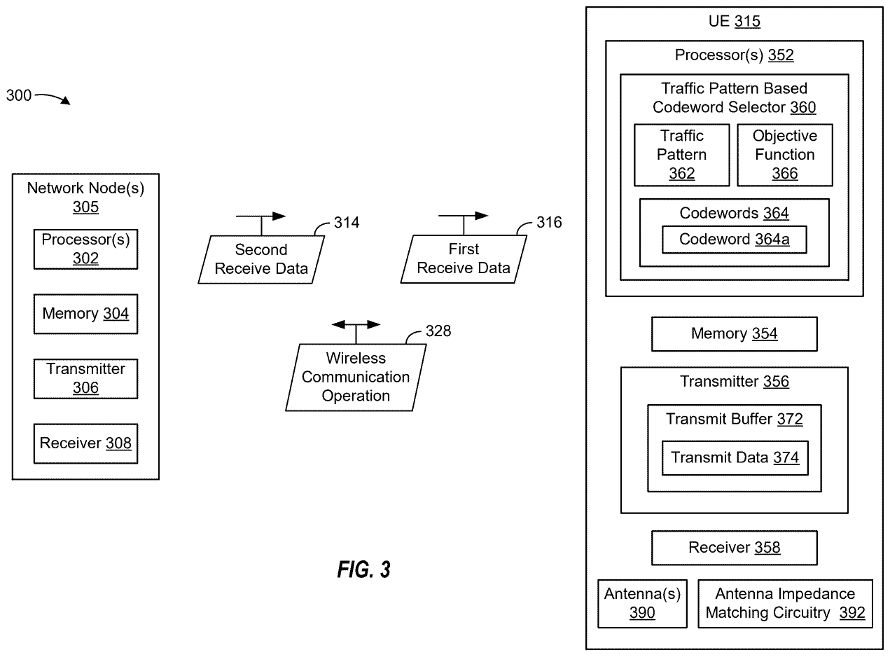

FIG. 3 is a block diagram illustrating an example wireless communication system 300 that supports traffic pattern based impedance matching. The wireless communication system 300 may include one or more UEs, such as a UE 315. In some examples, the UE 315 may correspond to the UE 115. The wireless communication system 300 may also include one or more network nodes 305. In some examples, the one or more network nodes 305 may include or may correspond to the base station 105. To further illustrate, the one or more network nodes 305 may include or may be implemented using one or more of a base station, a network controller, an integrated access and backhauling (IAB) node, a distributed unit (DU), a central unit (CU), or a remote/radio unit (RU) (which may also be referred to as a remote radio unit (RRU)), as illustrative examples.

A network node of the one or more network nodes 305 may include a processing system including one or more processors 302 (such as the controller 240) and one or more memories (such as a memory 304, which may correspond to the memory 242). The network node may further include a transmitter 306 and a receiver 308. The one or more processors 302 may be coupled to the memory 304, to the transmitter 306, and to the receiver 308. In some examples, the transmitter 306 and the receiver 308 may include one or more components described with reference to FIG. 2, such as one or more of the modulator/demodulators 232a-t, the MIMO detector 236, the receive processor 238, the transmit processor 220, or the TX MIMO processor 230. In some examples, the one or more processors 302 may be configured to individually or collectively perform one or more operations described herein.

The transmitter 306 may transmit reference signals, synchronization signals, control information, and data to one or more other devices, and the receiver 308 may receive reference signals, control information, and data from one or more other devices. For example, in some implementations, the transmitter 306 may transmit signaling, control information, and data to the UE 315, and the receiver 308 may receive signaling, control information, and data from the UE 315.

The UE 315 may include a processing system including one or more processors 352 (such as the controller 280) and one or more memories (such as a memory 354, which may correspond to the memory 282). The UE 315 may further include a transmitter 356 and a receiver 358. The one or more processors 352 may be coupled to the memory 354, to the transmitter 356, and to the receiver 358. In some examples, the transmitter 356 and the receiver 358 may include one or more components described with reference to FIG. 2, such as one or more of the modulator/demodulators 254a-r, the MIMO detector 256, the receive processor 258, the transmit processor 264, or the TX MIMO processor 266. In some implementations, the transmitter 356 and the receiver 358 may be integrated in one or more transceivers of the UE 315. In some examples, the one or more processors 352 may be configured to individually or collectively perform one or more operations described herein.

The UE 315 may also include one or more antennas 390. The one or more antennas 390 may include, for example, the antennas 252a-r of FIG. 2. The one or more antennas 390 may be coupled to one or more of the transmitter 356 or the receiver 358. The UE 315 may also include antenna impedance matching circuitry 392 coupled to the one or more antennas 390. In some implementations, the transmitter 356 may include a transmit buffer 372.

The transmitter 356 may transmit reference signals, synchronization signals, control information, and data to one or more other devices, and the receiver 358 may receive reference signals, control information, and data from one or more other devices. For example, in some implementations, the transmitter 356 may transmit signaling, control information, and data to the one or more network nodes 305, and the receiver 358 may receive signaling, control information, and data from the one or more network nodes 305. In some implementations, one or more of the transmitter 356 or the receiver 358 may utilize the one or more antennas 390 to transmit or receive signaling, respectively.

The wireless communication system 300 may use wireless communication channels, which may be specified by one or more wireless communication protocols, such as a 5G NR wireless communication protocol, a 6G wireless communication protocol, or another wireless communication protocol. To further illustrate, the one or more network nodes 305 may communicate with the UE 315 using one or more downlink wireless communication channels (such as via one or more of a PDSCH or a PDCCH). The UE 315 may communicate with the one or more network nodes 305 using one or more uplink wireless communication channels (such as via one or more of a PUSCH or a PUCCH). Alternatively, or in addition, the UE 315 may communicate with one or more other UEs, such as via a sidelink wireless communication channel. In some examples, the UE 315 may use the one or more antennas 390 to transmit or receive signaling using one or more such wireless communication channels.

During operation, the UE 315 may perform one or more wireless communication operations with the one or more network nodes 305 using the one or more antennas 390. In some aspects, the UE 315 may dynamically adjust impedance associated with the one or more antennas 390 using the antenna impedance matching circuitry 392. For example, the UE 315 may include, or may execute, a traffic pattern based codeword selector 360 that selects among a plurality of codewords, such as by selecting a codeword 364a from among codewords 364. Each of the codewords 364 may be associated with a respective setting (e.g., one or more of an aperture or an impedance) of the antenna impedance matching circuitry 392. Upon selecting the codeword 364a, the traffic pattern based codeword selector 360 may provide the codeword 364a to the antenna impedance matching circuitry 392 (e.g., to adjust one or more of an aperture or an impedance associated with the one or more antennas 390).

To further illustrate, in some examples, the antenna impedance matching circuitry 392 may include a set of switches coupled to a resistor-inductor-capacitor (RLC) circuit that includes one or more resistors, one or more inductors, and one or more capacitors. Each of the codewords 364 may correspond to a respective setting of the one or more switches that adjusts one or more of an aperture or an impedance associated with the one or more antennas 390 by changing a configuration of the RLC circuit (e.g., a combination of the one or more resistors, the one or more inductors, and the one or more capacitors).

After providing the codeword 364a to the antenna impedance matching circuitry 392, the UE 315 may perform one or more wireless communications in accordance with the codeword 364a. For example, the UE a wireless communication operation 328 associated with data indicated by the traffic pattern 362. Further, the UE 315 may use the codeword 364a (e.g., by adjusting one or more of an aperture or an impedance associated with the antenna impedance matching circuitry 392 in accordance with the codeword 364a) to perform the wireless communication operation 328.

In some aspects, the traffic pattern based codeword selector 360 may receive or determine a traffic pattern 362 and may select among the codewords 364 in accordance with the traffic pattern 362. In some examples, the traffic pattern based codeword selector 360 may use the traffic pattern 362 to determine whether to select a codeword that is more favorable to transmit operations by the transmitter 356 (and less favorable to receive operations by the receiver 358) or to select a codeword that is more favorable to receive operations by the receiver 358 (and less favorable to transmit operations by the transmitter 356). To illustrate, if the UE 315 is to transmit a relatively large amount of data and is to receive a relatively small amount of data (or no data), the UE 315 may select a codeword 364a that is more favorable to transmit operations by the transmitter 356 (and less favorable to receive operations by the receiver 358). As another example, if the UE 315 is to receive a relatively large amount of data and is to transmit a relatively small amount of data (or no data), the UE 315 may select a codeword 364a that is more favorable to receive operations by the receiver 358 (and less favorable to transmit operations by the transmitter 356). Depending on the example, a transmit operation may use an uplink channel or a sidelink channel, and a receive operation may use a downlink channel or a sidelink channel.

To further illustrate, in some examples, the traffic pattern 362 may indicate or may correspond to a quantity of transmit data 374 that is stored in the transmit buffer 372. The transmit data 374 may be scheduled to be transmitted by the UE 315 (e.g., to the one or more network nodes 305 or to another UE). To illustrate, the traffic pattern 362 may indicate whether the UE 315 is scheduled to transmit a large amount of transmit data 374, a small amount of transmit data 374, or no transmit data 374. In some such examples, performing the wireless communication operation 328 may include transmitting the transmit data 374 (e.g., to the one or more network nodes 305 via an uplink channel, or to another UE via a sidelink channel).

Alternatively, or in addition, the traffic pattern 362 may indicate or may correspond to a quantity of first receive data 316 received by the UE 315 during a particular time interval (e.g., a quantity of one or more slots). To illustrate, the UE 315 may measure, during the particular time interval, whether the UE 315 receives a large amount of receive data 316, a small amount of receive data 316 or no receive data 314. In some circumstances, by measuring the amount of first receive data 316 during the particular time interval, the UE 315 may estimate or predict an amount of second receive data 314 that is to be received by the UE 315 following the particular time interval. To illustrate, in some examples, the first receive data 316 and the second receive data 314 may be included in a common transmission or in a common set of data (e.g., a common file or other content, such as a streaming video). In some such examples, performing the wireless communication operation 328 may include receiving the second receive data 314 following the particular time interval (e.g., from the one or more network nodes 305 via a downlink channel, or from another UE via a sidelink channel).

In some examples, the UE 315 may select the codeword 364a by optimizing an objective function 366. In some examples, the objective function 366 may be associated with one or more of a bits-per-joule parameter, a latency parameter, a power consumption parameter, or another parameter. In some examples, the UE 315 may identify a subset of codewords from a codebook based on one or more criteria, and selecting the codeword may include sub-selecting the codeword 364a from the subset by optimizing the objective function 366 for the subset of codewords, as described further below.

After performing the wireless communication operation 328, the UE 315 may reselect among the codewords 364 (e.g., to dynamically change impedance associated with the one or more antennas 390). For example, the UE 315 may periodically perform the reselection or may perform the reselection in accordance with detecting one or more reselection trigger conditions. In an example, the codeword 364a may be associated with a first set of one or more slots, and the UE 315 may reselect among the codewords 364 (e.g., by selecting another codeword associated with the antenna impedance matching circuitry 392) for a second set of one or more slots following the first set of one or more slots. Accordingly, the UE 315 may dynamically modify an impedance associated with the one or more antennas 390, which may reflect, for example, changes in an amount of transmit data to be transmitted by the UE 315, changes in an amount of receive data to be received (or estimated to be received) by the UE 315, or both.

To further illustrate, in some examples, the UE 315 may dynamically select the codeword 364a for a first slot associated with the wireless communication operation 328 and further as a function of an application executed by the UE 315. The UE 315 may dynamically select a second codeword for a second slot following the first slot. In some examples, the UE 315 may dynamically select the second codeword as a function of one or more of a change in the traffic pattern 362, a change in the objective function 366, or a change in the application executed by the UE 315.

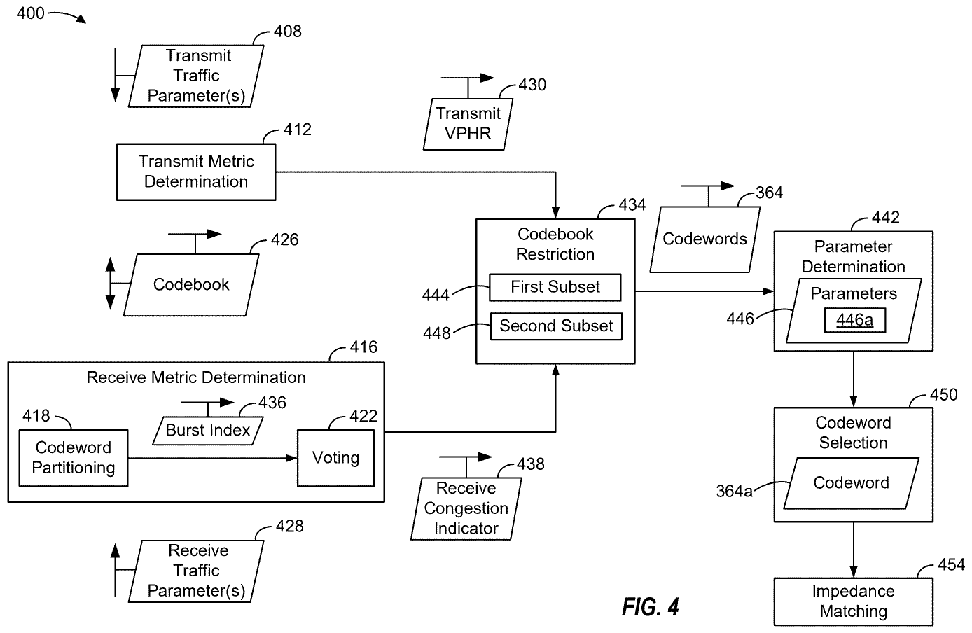

FIG. 4 is a block diagram illustrating examples of operations 400 that support traffic pattern based impedance matching. In some examples, the operations 400 may be performed by the traffic pattern based codeword selector 360 of FIG. 3.

The operations 400 may include determining one or more transmit metrics, at 412. In some examples, the one or more transmit metrics may be determined (at 412) based on one or more transmit traffic parameters 408, based on a codebook 426 of codewords, or based on a combination thereof. In some examples, the codebook 426 may indicate candidate settings associated with the antenna impedance matching circuitry 392, and the codeword 364a may correspond to a particular setting of the candidate settings. The one or more transmit traffic parameters 408 may be included in the traffic pattern 362 of FIG. 3. Further, in some examples, the one or more transmit metrics may include a transmit virtual power headroom report (VPHR) 430, which may be determined for each codeword of the codebook 426. Some illustrative examples that may be associated with determining the one or more transmit metrics are described further below.

The operations 400 may further include determining one or more receive metrics, at 416. In some examples, the one or more receive metrics may be determined (at 416) based on one or more receive traffic parameters 428, based on the codebook 426 of codewords, or based on a combination thereof. The one or more receive traffic parameters 428 may be included in the traffic pattern 362 of FIG. 3. Further, in some examples, the one or more receive metrics may include a receive congestion indicator 438.

In some implementations, determining the one or more receive metrics (at 416) may include performing codeword partitioning (e.g., to partition codewords of the codebook 426), at 418, and may further including performing voting, at 422. Further, in some examples, performing the codeword partitioning (at 418) may include generating a burst index 436, and the voting may be performed (at 422) based on the burst index 436. Some illustrative examples that may be associated with codeword portioning and voting are described further below.

The operations 400 may further include performing codebook restriction, at 434, such as by identifying a first subset 444 of codewords of the codebook 426 that satisfy one or more transmit-related criteria and by identifying a second subset 448 of codewords of the codebook 426 that satisfy one or more receive-related criteria. Performing the codebook restriction (at 434) may further include determining the plurality codewords 364 in accordance with an intersection of the first subset 444 and the second subset 448 (e.g., where the plurality codewords 364 corresponds to the intersection of the first subset 444 and the second subset 448).

The operations 400 may further include performing parameter determination 442 associated with the codewords 364 to determine parameters 446 (e.g., by evaluating the object function 366). For example, the parameters 446 may include a respective parameter associated with each codeword of the codewords 364. As an illustrative example, the parameters 446 may include a parameter 446a associated with the codeword 364a. In some examples, the parameters 446 may include or correspond to a weighted per-carrier throughput metric adjusted for power consumption. In some examples, the parameters 446 may include or correspond to bits-per-joule metrics. In such examples, the parameters 446 may include, for each of the codewords 364, a bits-per-joule metric. Other examples are also within the scope of the disclosure.

The operations 400 may further include performing codeword selection 450 of the codeword 364a from the codewords 364 in accordance with the parameters 446. To illustrate, performing the codeword selection 450 may include determining that a parameter 446a associated with the codeword 364a is greater than the other parameters of the parameters 446, such as by determining that a bits-per-joule metric associated with the codeword 364a exceeds bits-per-joule metrics associated with the other parameters of the parameters 446. In some examples, performing the codeword selection 450 may include using a maximum (max) function to determine the codeword 364a.

The operations 400 may further include performing impedance matching 454 based on the codeword 364a. For example, performing the impedance matching 454 may include adjusting a setting (e.g., one or more of an aperture or an impedance) of the antenna impedance matching circuitry 392 based on the codeword 364a.

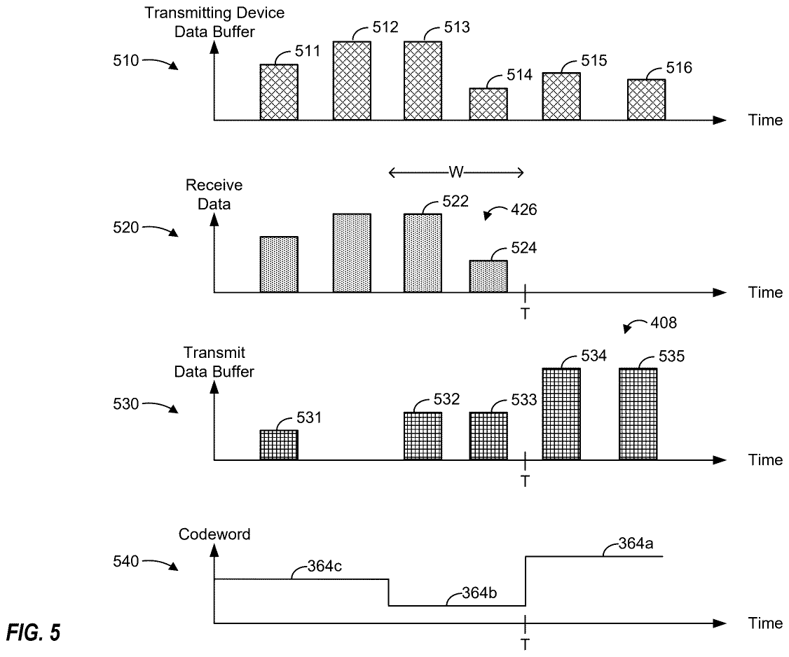

FIG. 5 is a block diagram illustrating examples of graphs 510, 520, 530, and 540 that may be associated with traffic pattern based impedance matching. In the graphs 510, 520, 530, and 540, the abscissa may indicate time. Further, in the graphs 510, 520, 530, and 540, the ordinate may indicate an amount of data in a transmitting device data buffer, an amount of receive data, an amount of data in a transmit data buffer, and a selected codeword, respectively. As referred to herein, an “amount of data” may refer to, or may be associated with, one or more of a quantity of time slots, a data size (such as a quantity of megabytes (MB)), or another metric.

Referring to the graph 510, data may be stored or buffered in a data buffer of a transmitting device and then transmitted to another device. For example, the transmitting device may correspond to the network node of the one or more network nodes 305. In some examples, the UE 315 may receive the transmitted data from the network node. To further illustrate, in some examples, the data may include data 511, 512, 513, 514, 515, and 516.

The graph 520 may illustrate data received by the UE 315. The data may include at least some of the transmitted data of the graph 510. In some examples, at time T, the UE 315 may estimate an amount of data likely to be received in one or more future slots by determining an amount of data received during a window W. For example, the UE 315 may estimate an amount of the data 515 and 516 to be received after time T by determining an amount of the data 522 and 524. In some examples, the amount of the data 522 and 524 may be indicated by the one or more receive traffic parameters 428. In some examples, the first receive data 316 of FIG. 3 may include the data 522 and 524, and the second receive data 314 may include the data 515 and 516.

The graph 530 may illustrate data transmitted by the UE 315, such as data 531, 532, 533, 534, and 535. The data 531-535 may be stored (e.g., buffered) at the transmit buffer 372. In some examples, the transmit data 374 may include the data 531-535. For example, prior to time T, the transmit buffer 372 may store the data 531-533, and the UE 315 may transmit the data 531-533. At time T, the transmit buffer 372 may store the data 534 and 535 (e.g., where the data 534 and 535 are scheduled to be transmitted during one or more time slots following time T). Further, in some examples, the one or more transmit traffic parameters 408 may indicate an amount of the data 534 and 535.

The graph 540 may indicate a change in codewords during operation of the UE 315. For example, the UE 315 may adjust from operating the antenna impedance matching circuitry 392 based on the codeword 364a, a codeword 364b, and a codeword 364c. The codewords 364a-c may be included in the codewords 364. At time T, the UE 315 may select another codeword, such as by selecting the codeword 364a based on the estimated amount of the data 515 and 516, based on the amount of the data 534 and 535, or a combination thereof. In some examples, following time T, the UE 315 may operate based on the codeword 364a for a time interval corresponding to the window W. In such examples, the UE 315 may reselect among the codewords 364 for each time interval corresponding to the window W.

In some examples, the codewords 364 may be indicated as cⱼ, where j indicates a positive integer. In some examples, the ordinate of the graph 540 may correspond to the value of j. Further, in some examples, the codeword 364a may be indicated as cₖ₊₁, the codeword 364b may be indicated as cₖ, and the codeword 364c may be indicated as cₖ₋₁, where k indicates a positive integer greater than one.

To further illustrate some aspects, in some examples, the UE 315 may perform codeword selection in accordance with the illustrative example of Equation 1:

$${ψ}_{𝒜} ( {c}_{j} , w ) = \frac{{Tput}_{Total , W e i g hted}}{{P}_{T o t a l}} . \qquad ( Equation 1 )$$

In the example of Equation 1, [symbol] (cⱼ, w) may correspond to the objective function 366. Further, cⱼ may indicate the jth codeword in codebook [symbol] (e.g., the codebook 426). Tput_{Total,Weighted} and P_{Total} may indicate a total, weighted throughput and a total power consumption, respectively.

In the example of Equation 1, the numerator of the right side of Equation 1 may indicate a quantity of bits, and the denominator of the right side of Equation 1 may indicate joules. Accordingly, [symbol] (cⱼ, w) may indicate a bits-per-joule metric for each respective codeword of the codewords 364. In some examples, the traffic pattern based codeword selector 360 may operate in accordance with the example of Equation 1, with another objective function, or a combination thereof (e.g., where the objective function may be changed dynamically during operation).

In some implementations, the codeword partitioning of FIG. 4 may including determining a VPHR for each codeword cⱼ, such as in accordance with Equation 2:

$${P}_{t x}^{V P H R} ( {c}_{j} ) = {P}_{t x} ( {c}_{j} ) {P}_{r e q} . \qquad ( Equation 2 )$$

In Equation 2,

$${P}_{t x}^{V P H R} ( {c}_{j} )$$

may correspond to the transmit VPHR 430 of FIG. 4. In some examples, Pₜₓ(cⱼ) may indicate a required transmit power to satisfy a power control metric (e.g., where closed-loop power control is utilized), and P_{req} may indicate a required power to clear the transmit buffer 372.

In some implementations, the receive metric determination of FIG. 4 may reduce or avoid a local minima condition that may be associated with impedance matching in some circumstances. In some examples, the receive metric determination of FIG. 4 may be performed in accordance with Equation 3:

$${γ}_{b} ( {c}_{k} ) = \frac{{VolServed}_{b} ( {c}_{k} )}{{VolAchieveable}_{b} ( {c}_{k} )} . \qquad ( Equation 3 )$$

In some examples, γ_{b}(cₖ) may indicate an amount that the UE 315 is “constrained” on a receive channel and correspond to the burst index 436 of FIG. 4.

In some examples, VolServed_{b}(cₖ) may indicate an amount of data volume served in a partition (e.g., index b), and VolAchieveable_{b}(cₖ) may indicate a theoretical amount of data that can be served. In some examples, the codeword partitioning may be performed based on a partition index p, where each partition may be of size

$$P = \frac{w}{{N}_{P}} .$$

Accordingly, in some aspects, codebooks for impedance matching may be generated for each antenna chain based on a current UE radio frequency (RF) configuration. The codebooks may be sub-selected for certain codewords, such as the “best” transmit codeword and the “best” receive codeword. A backward-looking window of W slots may be used based on a traffic pattern. Transmit and receive metrics may be determined for codebook restriction, and a codebook restrictor may be used to avoid local maxima and to generate a restricted codebook (e.g., [symbol] ). A parameter (such as a bits-per-joule metric) may be used in connection with the restricted codebook. A subsequent codework (e.g., cₖ₊₁) may be selected and used for the subsequent W slots. In some implementations, such operations may be repeated for each set of W slots.

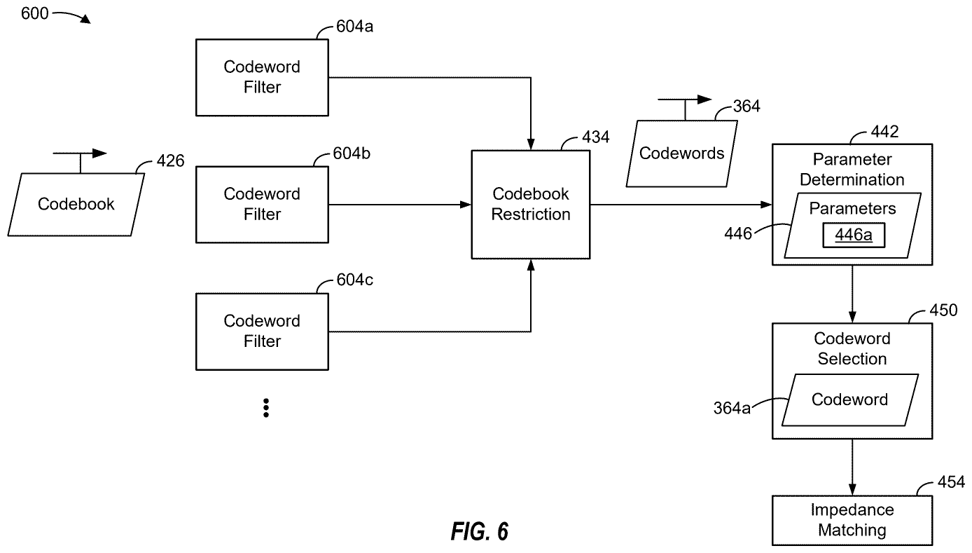

FIG. 6 is a block diagram illustrating additional examples of operations 600 that support traffic pattern based impedance matching. In some examples, the operations 600 may be performed by the traffic pattern based codeword selector 360 of FIG. 3.

In the example of FIG. 6, multiple codeword filters may be used, such as codeword filters 604a, 604b, and 604c. In some examples, the codeword filters 604a-c may include codeword filters associated with different wireless communication technologies. For example, the codeword filters 604a-c may include one or more codeword filters associated with cellular wireless communications and may further include one or more codeword filters associated with a wireless local area network (WLAN) or with a wireless personal area network (WPAN).

Alternatively, or in addition, the codeword filters 604a-c may include codeword filters associated with different component carriers (CCs). As an illustrative example, the codeword filter 604a may be associated with a first CC (e.g., a primary CC), the codeword filter 604b may be associated with a second CC (e.g., a secondary CC), and the codeword filter 604c may be associated with a WLAN. In the example of FIG. 6, the parameter determination 442 may be performed based at least in part on a quantity of CCs associated with the codeword filters 604a-c. Other examples are also within the scope of the disclosure.

In some examples, each different wireless communication technology (e.g., cellular, WLAN, and WPAN) may be associated with a different respective function ψ. As an illustrative example, a WLAN may be associated with a function ψ_{WLAN}(cⱼ, w). Further, in some implementations, different such functions ψ may be separately evaluated and then summed to determine an aggregate function ψ, which may correspond to a sum of the different contributions of the different functions ψ.

Although some examples may be described herein with reference to a bits-per-joule metric, other examples are also within the scope of the disclosure. To illustrative, examples of the parameters 446 may include, or may be based on, one or more of latency, reliability, signal-to-noise ratio (SNR), or another metric, as illustrative examples. Further, each function ψ may be selected or dynamically adjusted for different applications, such as for a voice call and for a gaming application, as illustrative examples.

By selecting the codeword 364a based on a traffic pattern associated with the UE 315 (e.g., based on the traffic pattern 362, the one or more transmit traffic parameters 408, the one or more receive traffic parameters 428, or a combination thereof), performance may be improved as compared to some other techniques, such as a technique that involves optimizing a minimum channel quality metric. For example, by selecting the codeword 364a based on an intersection of multiple subsets of codewords of the codebook 426 (e.g., the first subset 444 and the second subset 448), the codeword 364a may be optimized for the wireless communication operation 328. As a result, impedance matching may be enhanced for the wireless communication operation 328, which may improve quality and reliability of the wireless communication operation 328. Further, by enhancing impedance matching, the UE 315 may avoid increasing the size of the one or more antennas 390 and the antenna impedance matching circuitry 392 to compensate for reduced performance. As a result, one or more features herein may support an increase in size of one or more components (such as a display screen or a battery) of the UE 315 by facilitating reduction in the size of the one or more antennas 390, the antenna impedance matching circuitry 392, or both.

Although some examples herein may be described with reference to the UE 315, other examples are also within the scope of the disclosure. For example, a network node (such as the base station 105 or a network node 305) may include a traffic pattern based codeword selector 360 and may perform one or more operations described with reference to the UE 315.

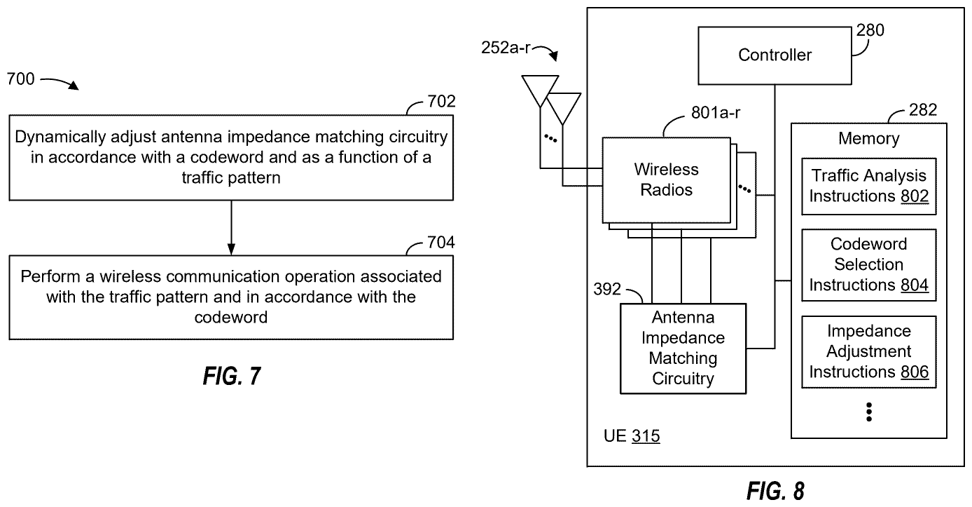

FIG. 7 is a flow chart of an example of a method 700 of wireless communication that supports traffic pattern based impedance matching. In some examples, the method 700 may be performed by a device, such as by a UE (e.g., the UE 115 or the UE 315), by a network node (e.g., the base station 105), or by another device.

The method 700 includes dynamically adjusting antenna impedance matching circuitry in accordance with a codeword and as a function of a traffic pattern, at 702. For example, the UE 315 may dynamically adjust an impedance of the antenna impedance matching circuitry 392 in accordance with a codeword of the codebook 426, such as in accordance with the codeword 364a. Further, the traffic pattern may include or may be based on one or more of the traffic patterns 362, the one or more transmit traffic parameters 408, the one or more receive traffic parameters 428, the transmit VPHR 430, the burst index 436, or the receive congestion indicator 438, as illustrative examples.

The method 700 further includes performing a wireless communication operation associated with the traffic pattern and in accordance with the codeword, at 704. For example, the UE 315 may perform the wireless communication operation 328 in accordance with the codeword 364a, and the wireless communication operation 328 may be associated with the traffic pattern 362.

FIG. 8 is a block diagram of an example UE 315 that supports traffic pattern based impedance matching. The UE 315 may include structure, hardware, or components illustrated in FIG. 2, FIG. 3, or a combination thereof. For example, the UE 315 may include the controller 280, which may execute instructions stored in the memory 282. Using the controller 280, the UE 315 may transmit and receive signals via wireless radios 801a-r and antennas 252a-r. The wireless radios 801a-r may include one or more components or devices described herein, such as the modulator/demodulators 254a-r, the MIMO detector 256, the receive processor 258, the transmit processor 264, the TX MIMO processor 266, the transmitter 356, the receiver 358, one or more other components or devices, or a combination thereof. In some examples, the antenna impedance matching circuitry 392 may be included in or may be coupled to one or more of the wireless radios 801a-r.

In some examples, a processing system may include one or more processors and one or more memories coupled to the one or more processors. The processing system may be configured to perform one or more operations described herein. To illustrate, in some examples, the memory 282 may store traffic analysis instructions 802 executable by the controller 280 to identify the traffic pattern 362. As another example, the memory 282 may store codeword selection instructions 804 executable by the controller 280 to select the codeword 364a in accordance with the traffic pattern 362. As an additional example, the memory 282 may store impedance adjustment instructions 806 executable by the controller 280 to adjust impedance of the antenna impedance matching circuitry 392.

In a first aspect, an apparatus for wireless communication includes a processing system including one or more processors and one or more memories coupled to the one or more processors. The processing system is configured to dynamically adjust antenna impedance matching circuitry in accordance with a codeword and as a function of a traffic pattern. The processing system is further configured to perform a wireless communication operation associated with the traffic pattern and in accordance with the codeword.

In a second aspect, in combination with the first aspect, the processing system is further configured to select the codeword by optimizing an objective function.

In a third aspect, in combination with one or more of the first aspect or the second aspect, the objective function is associated with one or more of a bits-per-joule parameter, a latency parameter, a power consumption parameter, or another parameter.

In a fourth aspect, in combination with one or more of the first aspect through the third aspect, the processing system is further configured to identify a subset of codewords from a codebook based on one or more criteria and to sub-select the codeword from the subset by optimizing the objective function for the subset of codewords.

In a fifth aspect, in combination with one or more of the first aspect through the fourth aspect, the processing system is further configured to execute an application, to dynamically select the codeword for a first slot associated with the wireless communication operation further as a function of the application, and to dynamically select a second codeword for a second slot following the first slot.

In a sixth aspect, in combination with one or more of the first aspect through the fifth aspect, the processing system is further configured to dynamically select the second codeword as a function of one or more of a change in the traffic pattern, a change in the objective function, or a change in the application.

In a seventh aspect, in combination with one or more of the first aspect through the sixth aspect, the codeword is included in a codebook of candidate settings associated with the antenna impedance matching circuitry, and the codeword corresponds to a particular setting of the candidate settings.

In an eighth aspect, a method of wireless communication performed by a device includes dynamically adjusting antenna impedance matching circuitry in accordance with a codeword and as a function of a traffic pattern. The method further includes performing a wireless communication operation associated with the traffic pattern and in accordance with the codeword.

In a ninth aspect, in combination with the eighth aspect, the method further includes selecting the codeword by optimizing an objective function.

In a tenth aspect, in combination with one or more of the eighth aspect through the ninth aspect, the objective function is associated with one or more of a bits-per-joule parameter, a latency parameter, a power consumption parameter, or another parameter.

In an eleventh aspect, in combination with one or more of the eighth aspect through the tenth aspect, the method further includes identifying a subset of codewords from a codebook based on one or more criteria, and selecting the codeword includes sub-selecting the codeword from the subset by optimizing the objective function for the subset of codewords.

In a twelfth aspect, in combination with one or more of the eighth aspect through the eleventh aspect, the codeword is dynamically selected for a first slot associated with the wireless communication operation further as a function of an application executed by the device, and the method further includes dynamically selecting a second codeword for a second slot following the first slot.

In a thirteenth aspect, in combination with one or more of the eighth aspect through the twelfth aspect, the second codeword is dynamically selected as a function of one or more of a change in the traffic pattern, a change in the objective function, or a change in the application executed by the device.

In a fourteenth aspect, in combination with one or more of the eighth aspect through the thirteenth aspect, the codeword is included in a codebook of candidate settings associated with the antenna impedance matching circuitry, and the codeword corresponds to a particular setting of the candidate settings.

In a fifteenth aspect, a non-transitory computer-readable medium stores instructions executable by one or more processors to initiate, perform, or control operations. The operations include dynamically adjusting antenna impedance matching circuitry in accordance with a codeword and as a function of a traffic pattern. The operations further include performing a wireless communication operation associated with the traffic pattern and in accordance with the codeword.

In a sixteenth aspect, in combination with the fifteenth aspect, the operations further include selecting the codeword by optimizing an objective function.

In a seventeenth aspect, in combination with one or more of the fifteenth aspect through the sixteenth aspect, the objective function is associated with one or more of a bits-per-joule parameter, a latency parameter, a power consumption parameter, or another parameter.

In an eighteenth aspect, in combination with one or more of the fifteenth aspect through the seventeenth aspect, the operations further include identifying a subset of codewords from a codebook based on one or more criteria, and selecting the codeword includes sub-selecting the codeword from the subset by optimizing the objective function for the subset of codewords.

In a nineteenth aspect, in combination with one or more of the fifteenth aspect through the eighteenth aspect, the codeword is dynamically selected for a first slot associated with the wireless communication operation further as a function of an application executed by the one or more processors, and the operations further include dynamically selecting a second codeword for a second slot following the first slot as a function of one or more of a change in the traffic pattern, a change in the objective function, or a change in the application executed.

In a twentieth aspect, in combination with one or more of the fifteenth aspect through the nineteenth aspect, the codeword is included in a codebook of candidate settings associated with the antenna impedance matching circuitry, and the codeword corresponds to a particular setting of the candidate settings.

In the figures, a single block may be described as performing a function or functions: The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including components such as a processor, memory, and the like.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or process disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus for wireless communication, the apparatus comprising:
a processing system including one or more processors and further including one or more memories coupled to the one or more processors, the processing system configured to:
dynamically adjust antenna impedance matching circuitry in accordance with a codeword and as a function of a traffic pattern; and
perform a wireless communication operation associated with the traffic pattern and in accordance with the codeword.

2. The apparatus of claim 1, wherein the processing system is further configured to select the codeword by optimizing an objective function.

3. The apparatus of claim 2, wherein the objective function is associated with one or more of a bits-per-joule parameter, a latency parameter, a power consumption parameter, or another parameter.

4. The apparatus of claim 2, wherein the processing system is further configured to identify a subset of codewords from a codebook based on one or more criteria and to sub-select the codeword from the subset by optimizing the objective function for the subset of codewords.

5. The apparatus of claim 2, wherein the processing system is further configured to:
execute an application;
dynamically select the codeword for a first slot associated with the wireless communication operation further as a function of the application; and
dynamically select a second codeword for a second slot following the first slot.

6. The apparatus of claim 5, wherein the processing system is further configured to dynamically select the second codeword as a function of one or more of a change in the traffic pattern, a change in the objective function, or a change in the application.

7. The apparatus of claim 1, wherein the codeword is included in a codebook of candidate settings associated with the antenna impedance matching circuitry, and wherein the codeword corresponds to a particular setting of the candidate settings.

8. A method of wireless communication performed by a device, the method comprising:
dynamically adjusting antenna impedance matching circuitry in accordance with a codeword and as a function of a traffic pattern; and
performing a wireless communication operation associated with the traffic pattern and in accordance with the codeword.

9. The method of claim 8, further comprising selecting the codeword by optimizing an objective function.

10. The method of claim 9, wherein the objective function is associated with one or more of a bits-per-joule parameter, a latency parameter, a power consumption parameter, or another parameter.

11. The method of claim 9, further comprising identifying a subset of codewords from a codebook based on one or more criteria, wherein selecting the codeword includes sub-selecting the codeword from the subset by optimizing the objective function for the subset of codewords.

12. The method of claim 9, wherein the codeword is dynamically selected for a first slot associated with the wireless communication operation further as a function of an application executed by the device, and further comprising dynamically selecting a second codeword for a second slot following the first slot.

13. The method of claim 12, wherein the second codeword is dynamically selected as a function of one or more of a change in the traffic pattern, a change in the objective function, or a change in the application executed by the device.

14. The method of claim 8, wherein the codeword is included in a codebook of candidate settings associated with the antenna impedance matching circuitry, and wherein the codeword corresponds to a particular setting of the candidate settings.

15. A non-transitory computer-readable medium storing instructions executable by one or more processors to initiate, perform, or control operations, the operations comprising:
dynamically adjusting antenna impedance matching circuitry in accordance with a codeword and as a function of a traffic pattern; and
performing a wireless communication operation associated with the traffic pattern and in accordance with the codeword.

16. The non-transitory computer-readable medium of claim 15, wherein the operations further comprise selecting the codeword by optimizing an objective function.

17. The non-transitory computer-readable medium of claim 16, wherein the objective function is associated with one or more of a bits-per-joule parameter, a latency parameter, a power consumption parameter, or another parameter.

18. The non-transitory computer-readable medium of claim 16, wherein the operations further comprise identifying a subset of codewords from a codebook based on one or more criteria, and wherein selecting the codeword includes sub-selecting the codeword from the subset by optimizing the objective function for the subset of codewords.

19. The non-transitory computer-readable medium of claim 16, wherein the codeword is dynamically selected for a first slot associated with the wireless communication operation further as a function of an application executed by the one or more processors, and wherein the operations further comprise dynamically selecting a second codeword for a second slot following the first slot as a function of one or more of a change in the traffic pattern, a change in the objective function, or a change in the application executed.

20. The non-transitory computer-readable medium of claim 15, wherein the codeword is included in a codebook of candidate settings associated with the antenna impedance matching circuitry, and wherein the codeword corresponds to a particular setting of the candidate settings.
